(19) United States
(12) Patent Application Publication
(10) Pub. No.: US 2016/0007778 A1
(43) Pub. Date: Jan. 14, 2016

(54) ADJUSTABLE ELECTRONIC DEVICE HOLDER

(71) Applicant: Tai Thanh Kien, Lowell, MA (US)

(72) Inventor: Tai Thanh Kien, Lowell, MA (US)

(21) Appl. No.: 14/682,370

(22) Filed: Apr. 9, 2015

Related U.S. Application Data
(60) Provisional application No. 61/977,181, filed on Apr. 9, 2014.

(51) Int. Cl. A47G 9/10; H05K 5/02; F16M 11/40

(52) U.S. Cl. CPC A47G 9/1045; F16M 11/40; H05K 5/0204; A47G 2009/1018

(57) ABSTRACT

The present invention provides a pillow-based adjustable apparatus configured to hold electronic devices that are normally hand-held such as electronic book readers, tablet computers, video MP3 players, mobile telephones and PDAs while traveling or at home.

### RELATED APPLICATION

This application claims the benefit of U.S. Provisional Application No. 61/977,181, filed on Apr. 9, 2014. The entire teaching of the above application is incorporated herein by reference.

### FIELD OF THE INVENTION

The present invention relates to article holding devices, and more particularly, to an adjustable apparatus for holding a normally handheld electronic device hands-free. Specifically, the present invention is a portable, adjustable, and hands-free apparatus for holding electronic devices such as electronic book readers, tablet computers, video MP3 players, mobile telephones and PDAs while traveling or at home.

### BACKGROUND OF THE INVENTION

Users of portable electronic devices, particularly those with video screens, often desire hands-free operation when traveling and when at home. Often, this need is based on user fatigue from holding a device with a video screen at an appropriate distance and viewing angle. Cases which fold and prop the devices at an appropriate angle are widely available. However, in order to be useful, these cases typically require a flat and stable surface such as a table top or airline seatback tray when traveling. Notably, these types of cases are not useful when a user is reclined such as on a couch, bed, or in an airline seat and need to be hand held. The act of holding the devices in awkward positions can induce undesirable hand, shoulder and arm strains.

A number of pillow-based electronic device holders exist, which support electronic devices such as those mentioned above by having the user rest a pillow with one face on her lap and then shaping a second face of the pillow such that the second face slopes upward and away from the user. The device rests on the second face with the screen towards the user for viewing. Typically, these pillows work best when the user is reclined, such that the lap is extended away from the torso, which keeps the one pillow face flat on the users lap for stability and provides an optimal viewing angle and distance for the portable electronic device. The user's head may also be angled back comfortably while still maintaining a view of the device screen. Notably, when the user is sitting upright, the device is much closer to the torso and the viewing angle much more severe. When in an upright position, a user of such an apparatus will be required to tilt their head downward in order to view the screen of the device. Also, such devices are prone to sliding off if the user falls asleep because they are merely resting on the lap unsecured. Overheating of devices due to the cushion blocking airflow across and through the device is not uncommon.

Other adjustable electronic device holders exist, which offer more flexibility of viewing distances and viewing angles than those of the pillow-based device holders. Typically, these device holders comprise a fixed base and an adjustable arm. The fixed bases include stands, such as those found on floor lamps, wall-mount bases, and clamping bases that mechanically squeeze a table, workbench or similar edge for support. Although there is some slight degree of mobility in these types of electronic device holders, they are not portable in the sense that they are convenient to carry and travel with.

In light of the problems and of the previously mentioned electronic device holders, it is therefore an object of the current invention to provide an electronic device holder which features the flexibility of the fixed-base holders and which overcomes the limitations of the existing pillow-based holders.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1 depicts a perspective view of the invention configured for use with the pillow comprising two pieces.

FIG. 2 depicts more contour detail of a two-piece pillow.

FIG. 3 depicts a two-piece pillow configured for storage or use as a pillow.

FIG. 4 depicts optional storage compartments within a pillow half.

FIG. 5 depicts a side view of a one-piece pillow with a support platform.

FIG. 6 depicts an overhead view of a support platform embodiment.

### SUMMARY OF THE INVENTION

The current invention describes an apparatus for holding an electronic device hands-free and includes at least an under-leg pillow having a mount within, a device holder having a mount, a flexible arm configured at a first end to operatively couple with the mount embedded within the pillow and a second end configured to operatively couple with the mount of the device holder. The flexible arm is adjustable such that the device holder, when attached, may be varied in both height and distance relative to the mount embedded within the pillow. The under-leg pillow may be one piece or it may comprise multiple pieces which may be adjusted to different configurations, including but not limited to, usage and storage.

A general object of this invention is to provide a pillow-based adjustable apparatus configured to hold electronic devices that are normally hand-held such as electronic book readers, tablet computers, video MP3 players, mobile telephones and PDAs while traveling or at home.

Another object of this invention is to provide an adjustable apparatus such that the user may vary the height and distance of the held device relative to the pillow base, thereby allowing optimal viewing angle and distance.

Yet another object of this invention is to provide the adjustable apparatus, having a pillow base that supports the user's legs from underneath and behind the knees, which provides comfort and utility in that it need not be affixed to any other objects nor does it need to extend to the floor in order to serve as a stabile base.

Other objects and advantages of the present invention will become apparent from the description and drawings which follow.

### DETAILED DESCRIPTION OF THE INVENTION

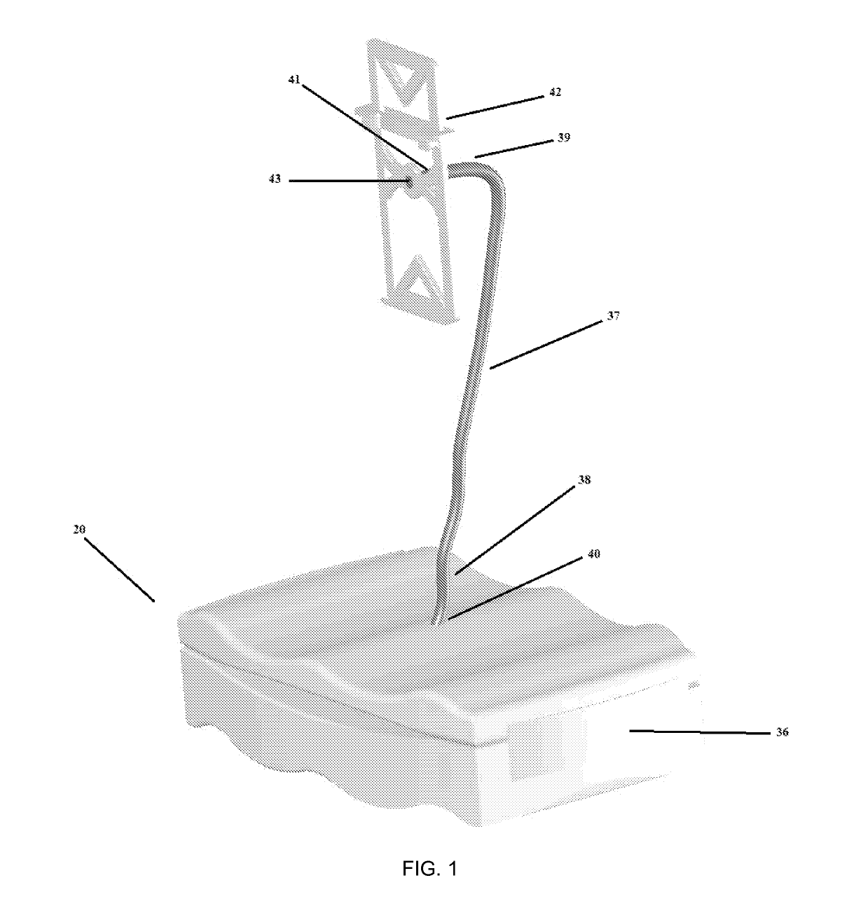

As shown in FIG. 1, a preferred embodiment of the pillow-based electronic device holder comprises a pillow 20 featuring a first face and a second face, at least one mount 25 disposed within the pillow, a device holder 42, a mount 43 affixed to the device holder 42, at least one flexible arm 37 which features a distal end 38 and a proximal end 39, a coupling 40 affixed to the distal end 38 of the at least one flexible arm 37 that operably engages with the at least one mount 25 disposed within the pillow 20, a coupling 41 affixed to the proximal end of the flexible arm 37 that operably engages with the mount 43 affixed to the device holder 42, and wherein the device holder 42 is capable of securing a portable electronic device. The pillow 20 may be between 12 and 20 inches in length and between 6 and 20 inches in width at its outer dimensions. The at least one mount 25 disposed within the pillow 20 is either flush or recessed with respect to the first face of the pillow. The thickness of the pillow 20 may be between 1 and 4 inches. The pillow is made from closed-cell foam or other suitable materials that may be shaped or molded, are washable, and provide sufficient compression resistance to be comfortable when used under the legs or head.

The mount 25 disposed within the pillow 20 and the mount 43 affixed to the device holder 42 may be the female portion of a threaded insert, or the female portion of a bayonet-type lug fastener, while the couplings 40, 41 affixed to the distal end 38 and proximal end 39 of the flexible arm 37 are the male counterparts to the aforementioned mounts 25, 43. Various embodiments allow the mounts 25, 43 and couplings 40, 41 to include other types of hardware capable of coupling in such a manner as to provide rigid support to the flexible arm 37 so long as the mount 25 disposed within the pillow 20 is either recessed or flush with respect to the pillow surface.

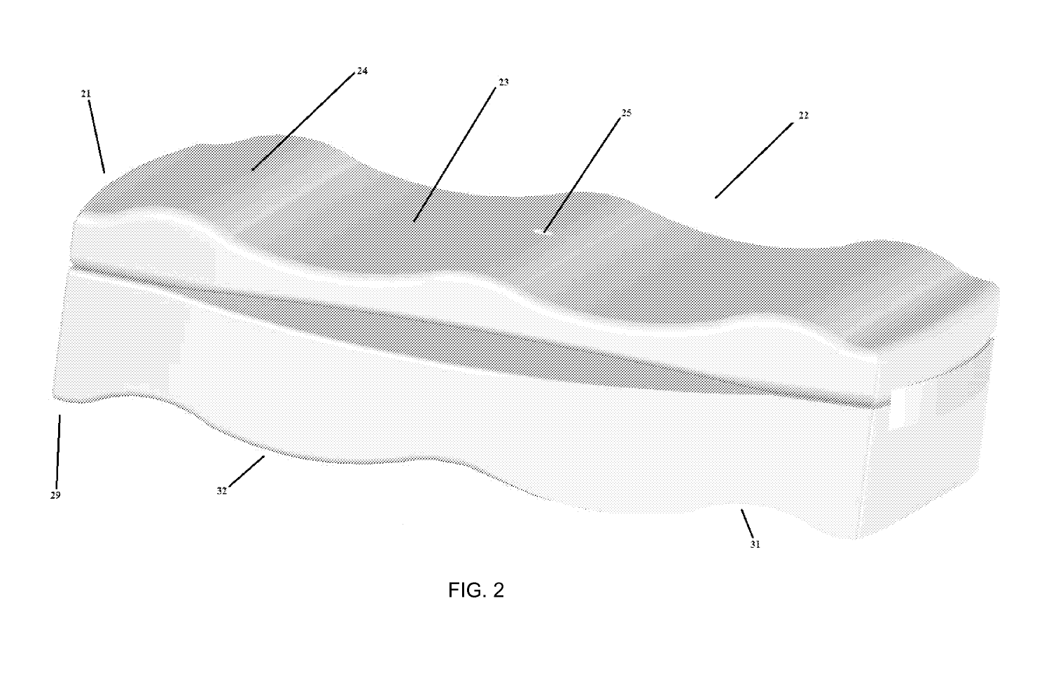

In another embodiment of the invention partially depicted in FIG. 2, the pillow 20 comprises a first pillow half 21 featuring a first face 22 and a second face 26, a second pillow half 29 featuring a first face 30 and a second face 33, and a hinge 36. The at least one mount 25 is disposed within the first face 22 of the first pillow half 21. The first face 22 of the first pillow half 21 comprises at least one concave radius 23 and at least one convex radius 24. The second face 26 of the first pillow half 21 comprises at least one concave radius 27. The first face 30 of the second pillow half 29 comprises at least one concave radius 31 and at least one convex radius 32. The second face 33 of the second pillow half 29 comprises at least one concave radius 34. The at least one convex radius 24 and at least one concave radius 23 of the first face 22 of the first pillow half 21 are the respective inverses of the at least one convex radius 32 and the at least one concave radius 31 of the first face 30 of the second pillow half 29.

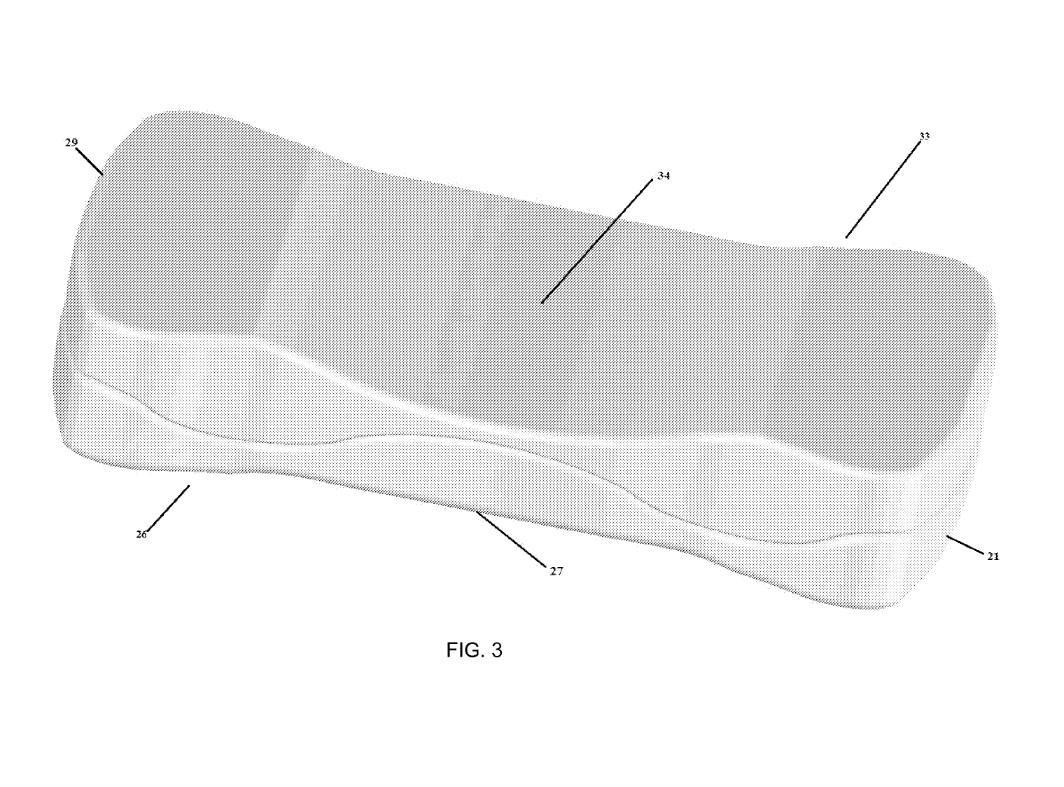

In this embodiment, when the first faces 22, 30 of the respective pillow halves 21, 29 are mated, they form a largely solid and supportive contiguous structure as shown in FIG. 3. This is the desired configuration when the device is not in use. The at least one concave radius 27 of the second face 26 of the first pillow half 21 has the same radius as the at least one concave radius 34 of the second face 33 of the second pillow half. The first pillow half 21 and the second pillow half are each between 1 and 4 inches in thickness, between 12 and 20 inches in length and between 6 and 20 inches in width at their outside dimensions.

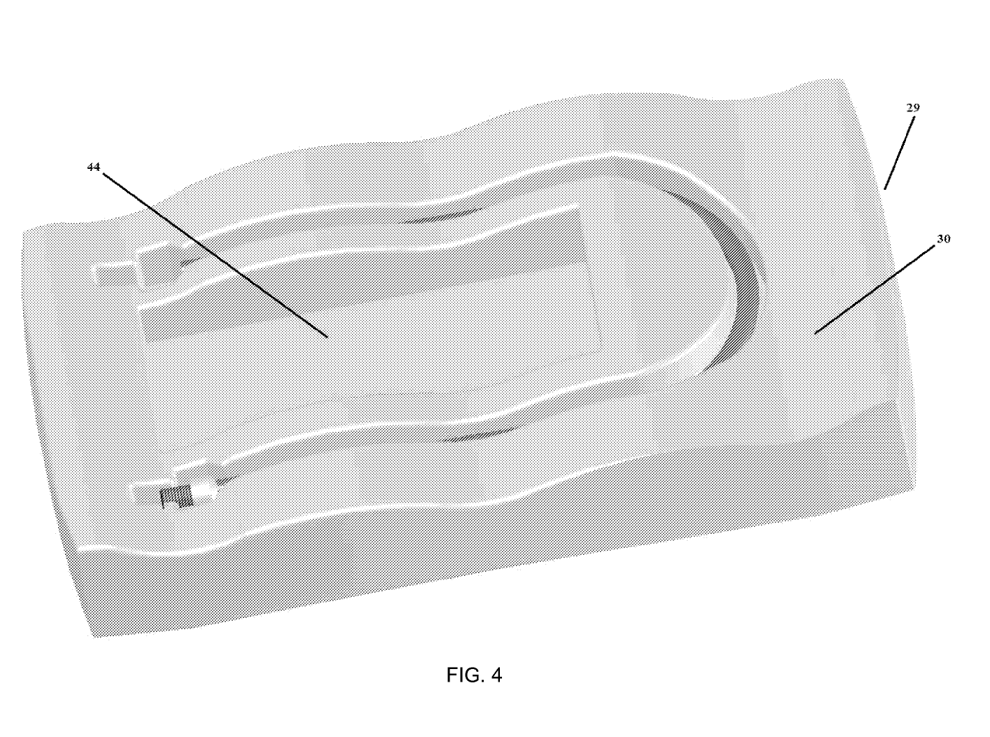

As shown in FIG. 4, an optional storage compartment 44 may be molded in the first faces 22, 30 of either or both pillow halves 21, 29. The storage compartment 44 serves to hold the at least one flexible arm 37 and the device holder 42 when not in use.

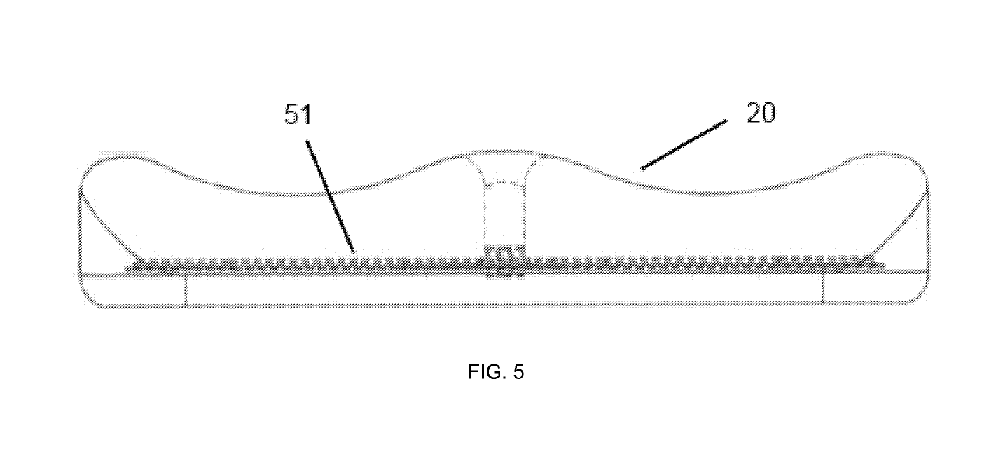

As shown in FIG. 5, a support platform 51 may be embedded within the pillow 20 or first pillow half 21 and affixed to the at least one mount in order to provide more rigidity and thus better support for the at least one mount 25. This support extends outward from the at least one mount in a lateral plane in order to distribute the forces transferred from the at least one flexible arm 37 and the electronic device it supports.

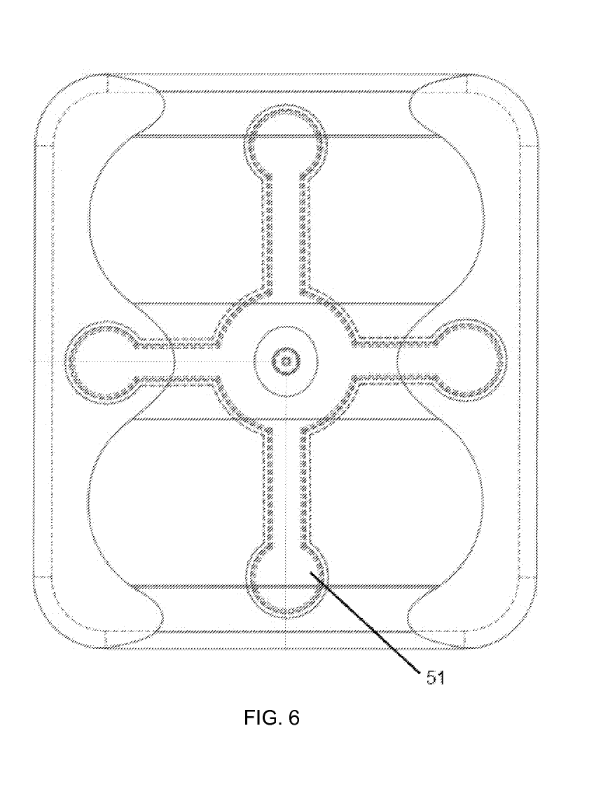

As shown in FIG. 6, one possible embodiment of the support platform 51 may comprise a hub-and-spoke configuration. Other contemplated embodiments of the support platform 51 may comprise a contiguous single plate, a web of spokes in varying geometries or a combination thereof.

While this invention has been particularly shown and described with references to preferred embodiments thereof, it will be understood by those skilled in the art that various changes in form and details may be made therein without departing from the scope of the invention put forth by the inventor.

What is claimed is:

1. An electronic device holder, the electronic device holder comprising: a pillow featuring a first face and a second face, at least one first mount disposed within the pillow, a device holder, at least one second mount affixed to the device holder, at least one flexible arm featuring a distal end and a proximal end, a first coupling affixed to the distal end of the at least one flexible arm, a second coupling affixed to the proximal end of the at least one flexible arm, and wherein: the at least one first mount is either flush or recessed with respect to the first face of the pillow, the first coupling operably engages with the at least one first mount and the second coupling operably engages with the at least one second mount and the device holder is capable of securing a portable electronic device.

2. The electronic device holder of claim 1, wherein a support platform is embedded within the pillow and the at least one first mount is affixed to the support platform.

3. The electronic device holder of claim 1, wherein the pillow is approximately rectangular in shape and at its outer dimensions is between 12 and 20 inches in length inclusive, between 6 and 20 inches in width inclusive, and between 1 and 4 inches in thickness inclusive.

4. The electronic device holder of claim 1, wherein the first face of the pillow comprises at least one concave radius and at least one convex radius.

5. The electronic device holder of claim 1, wherein the pillow material comprises closed cell foam or similar material that will provide compression resistance when used under the legs or head.

6. The electronic device holder of claim 1, wherein the pillow material is hypoallergenic.

7. The electronic device holder of claim 1, wherein the pillow comprises a first pillow half featuring a first face and a second face, a second pillow half featuring a first face and a second face, and a hinge.

8. The electronic device holder of claim 7, wherein the at least one first mount is disposed within the first pillow half.

9. The electronic device holder of claim 7, wherein: the first face of the first pillow half comprises at least one concave radius and at least one convex radius; the second face of the first pillow half comprises at least one concave radius; the first face of the second pillow half comprises at least one concave radius and at least one convex radius; the second face of the second pillow half comprises at least one concave radius; and the at least one convex radius and at least one concave radius of the first face of the first pillow half are the respective inverses of the at least one convex radius and the at least one concave radius of the first face of the second pillow half.

10. The electronic device holder of claim 7, wherein the first faces of either or both of the first pillow half or the second pillow further comprise an optional storage compartment.
